(19) United States
(12) Patent Application Publication
(10) Pub. No.: US 2025/0385218 A1
(43) Pub. Date: Dec. 18, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Yu-Chun Chen, Kaohsiung City (TW); Teng-Chuan Hu, Tainan City (TW); I-Ming Tseng, Kaohsiung City (TW); Chung-Sung Chiang, Kaohsiung City (TW); Yi-An Shih, Changhua County (TW); Chiu-Jung Chiu, Tainan City (TW); Chiao-Hui Tu, Tainan City (TW)

(73) Assignee: UNITED MICROELECTRONICS CORP., Hsin-Chu City (TW)

(21) Appl. No.: 18/770,680

(22) Filed: Jul. 12, 2024

(30) Foreign Application Priority Data
Jun. 12, 2024 (TW) 113121640

(51) Int. Cl. H01L 23/00; H01L 21/306; H01L 23/31; H01L 23/522; H01L 25/00; H01L 25/065

(52) U.S. Cl. CPC H01L 24/80; H01L 21/30625; H01L 23/3171; H01L 23/5226; H01L 24/03; H01L 24/08; H01L 24/09; H01L 25/0657; H01L 25/50; H01L 2224/0391; H01L 2224/08145; H01L 2224/09181; H01L 2224/80895; H01L 2224/80896; H01L 2225/06503

(57) ABSTRACT

A method for fabricating semiconductor device includes the steps of first bonding a top wafer to a bottom wafer, performing an edge trimming process to remove part of the top wafer, forming a pad layer on the top wafer, performing a first etching process to remove part of the pad layer to form a bonding pad, forming a first passivation layer on the bonding pad, and then performing a second etching process to remove part of the first passivation layer.

### BACKGROUND OF THE INVENTION

### 1. Field of the Invention

The invention relates to a method for fabricating semiconductor device, and more particularly, to a method of bonding two wafers and then forming passivation layer on sidewalls of the top wafer.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (POP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating semiconductor device includes the steps of first bonding a top wafer to a bottom wafer, performing an edge trimming process to remove part of the top wafer, forming a pad layer on the top wafer, performing a first etching process to remove part of the pad layer to form a bonding pad, forming a first passivation layer on the bonding pad, and then performing a second etching process to remove part of the first passivation layer.

According to another aspect of the present invention, a semiconductor device includes a top wafer bonded to a bottom wafer, in which the top wafer includes a metal interconnect structure, a bonding pad on the metal interconnect structure, and a first passivation layer on a sidewall of the bonding pad. The semiconductor device further includes a first gap between an edge of the first passivation layer and an edge of the metal interconnect structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a semiconductor device according to an embodiment of the present invention.

FIG. 7 illustrates a structural view of a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

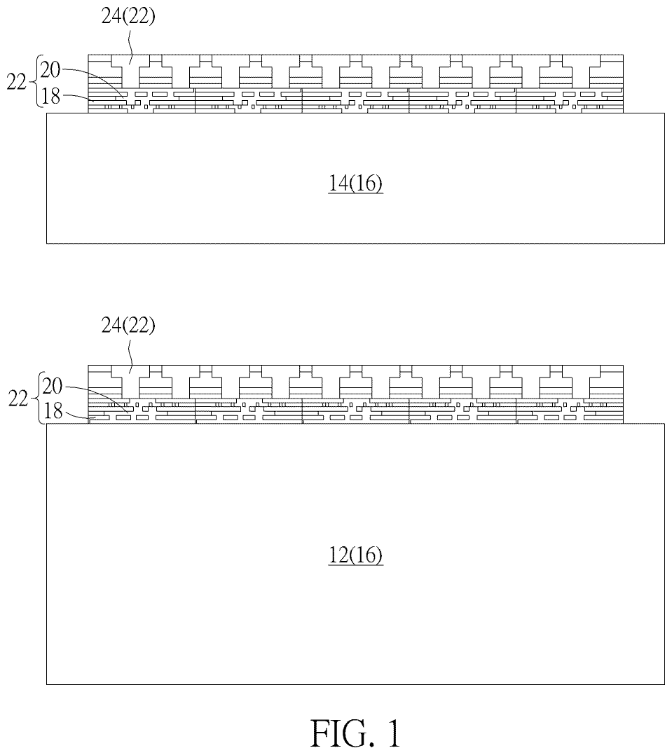

Referring to FIGS. 1-6, FIGS. 1-6 illustrate a method for fabricating a semiconductor device according to an embodiment of the present invention. As shown in FIG. 1, a bottom wafer 12 and a top wafer 14 both made of semiconductor material are provided. Preferably, each of the bottom wafer 12 and top wafer 14 includes a substrate 16 made of semiconductor materials, the substrates 16 could have same or different thicknesses depending on the fabrication or demand of the product, and each of the substrates 16 could also be made of semiconductor substrate material including but not limited to for example silicon substrate, epitaxial silicon substrate, silicon carbide substrate or even a silicon-on-insulator (SOI) substrate, which are all within the scope of the present invention. In this embodiment, each of the wafers 12, 14 could be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the bottom wafer 12 and top wafer 14 respectively. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers and metal interconnections on the aforementioned active devices and/or passive devices.

If a MOS transistor were to be fabricated, the FEOL process could include the steps of forming a gate structure on the substrate 16, forming a spacer (not shown) adjacent to sidewalls of the gate structure and a source/drain region in the substrate 16 adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 16 to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer 18 disposed on the ILD layer, and metal interconnections 20 in the IMD layer 18 for connecting the contact plugs, in which the IMD layer 18 and the metal interconnections 20 could constitute a metal interconnect structures 22 altogether and the topmost metal interconnection on front side of each of the wafers 12, 14 could be used as connecting junctions such as direct bond interconnects (DBIs) 24 as the two wafers could be bonded through DBIs 24 in the later process. In this embodiment, the ILD layer and the IMD layer 18 could include oxides including but not limited to for example tetraethyl orthosilicate (TEOS) and the contact plugs, the metal interconnections 20, and the DBIs 24 could include Al, Cr, Cu, Ta, Mo, W, or combination thereof.

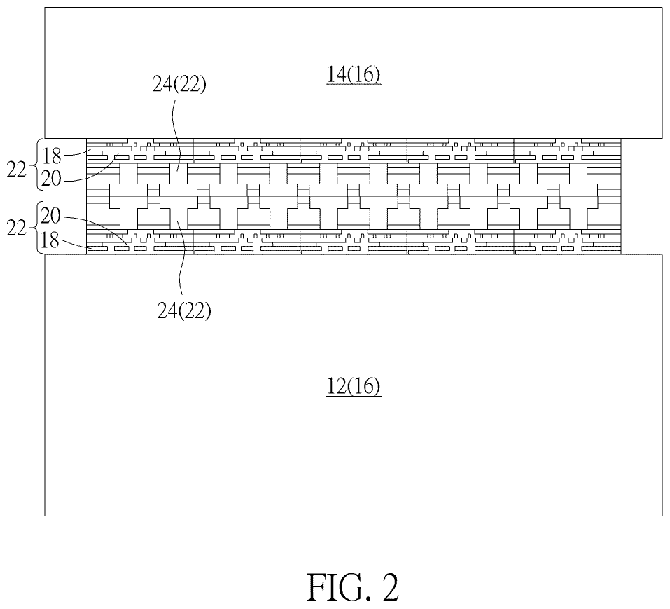

Next, as shown in FIG. 2, a hybrid bonding process is conducted by using the DBIs to connect the bottom wafer 12 and the top wafer 14. Preferably, the bonding process could be accomplished by first reversing the top wafer 14 so that the front side of the top wafer 14 or the exposed surface of the DBIs 24 is facing toward the front side of the bottom wafer 12 or the exposed surface of the DBIs 24, and then performing a thermal treatment process to directly bond the two wafers 12, 14 by directly contacting the DBIs 24 on both wafers 12, 14 so that the DBIs 24 and IMD layer 18 on the top wafer 14 directly contacting the DBIs 24 and IMD layer 18 on the bottom wafer 12.

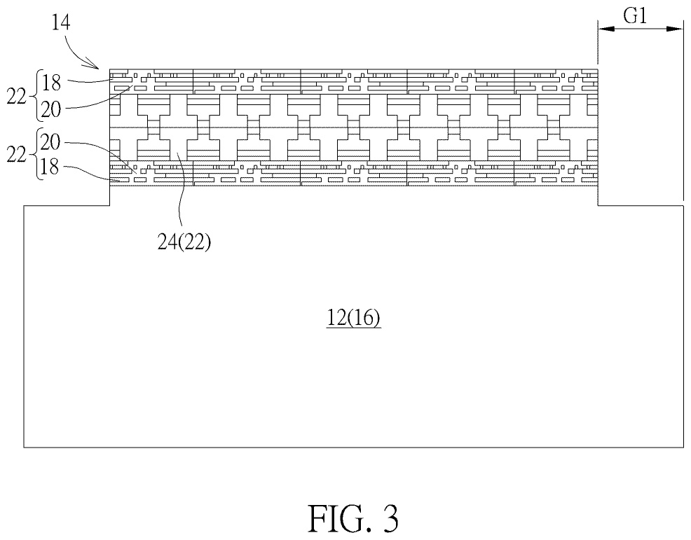

Next, as shown in FIG. 3, a planarizing process such as chemical mechanical polishing (CMP) process is conducted to remove major portion or even all of the substrate 16 of the top wafer 14 while the metal interconnect structure 22 on the substrate 16 is maintained and then an edge trimming process is conducted to remove part of the top wafer 14. Specifically, the edge trimming process could be accomplished by using a dicing or back grinding tool to remove part of the edge of the top wafer 14 so that the overall width of the remaining top wafer 14 is less than the overall width of the bottom wafer 12.

It should be noted that the edge trimming process conducted at this stage not only removes part of the edge of the top wafer 14, but could also remove part of the edge of the bottom wafer 12 after removing edges of the top wafer 14 so that top surface of the edge of the bottom wafer 12 is slightly lower than the top surface of the central portion of the bottom wafer 12 while sidewalls of the top wafer 14 are aligned with part of the sidewalls of the bottom wafer 12. In other words, after the edge trimming process is conducted, a distance or gap G1 is formed between an edge of the metal interconnect structure 22 of the top wafer 14 and an edge of the substrate 16 of the bottom wafer 12. Moreover, after most of the substrate 16 of the top wafer 14 is removed by the planarizing process, the thickness of the metal interconnect structure 22 of the remaining top wafer 14 is preferably less than 10 microns while the overall thickness of the bottom wafer 12 including both the substrate 16 and the metal interconnect structure 22 is between 700-800 microns or most preferably 750 microns.

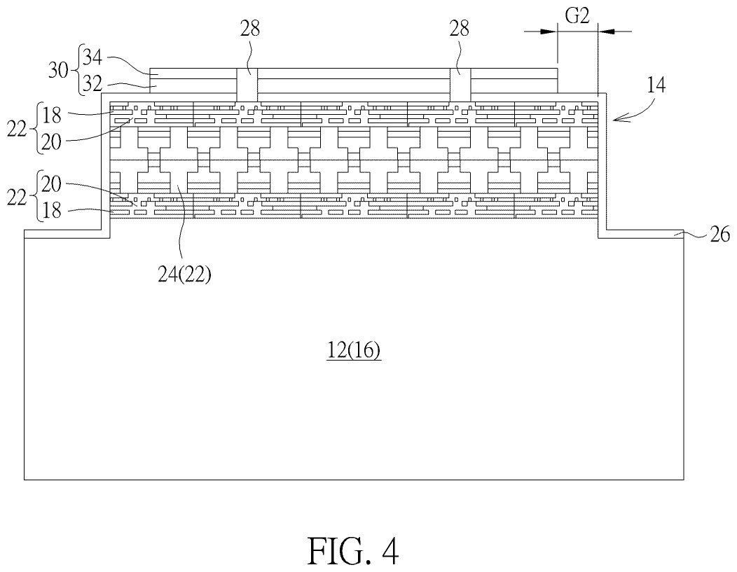

Next, as shown in FIG. 4, a liner 26 could be formed on the metal interconnect structure 22 to cover sidewalls of the top wafer 14 and sidewalls of the metal interconnect structure 22 and top surface of the edge portion of the bottom wafer 12, a passivation layer 30 is formed on the liner 26, and then a plurality of deep vias 28 are formed in the passivation layer 30. In this embodiment, the formation of the passivation layer 30 and the deep vias 28 could be accomplished by first forming a passivation layer 32 and another passivation layer 34 on the metal interconnection structure 22 and then using a photo-etching process to remove part of the passivation layer 34 and part of the passivation layer 32 for forming another gap G2 between an edge of the remaining passivation layers 32, 34 and an edge of the metal interconnect structure 22. Next, a pattern transfer process could be conducted by using a patterned mask (not shown) as mask to remove part of the passivation layer 34 and part of the passivation layer 32 to form contact holes or deep via openings (not shown) exposing the metal interconnections 20 underneath.

Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes or deep via openings, and then a planarizing process such as CMP could be conducted to remove part of the conductive materials to form deep vias 28 electrically connecting or directly contacting the metal interconnections 20. In this embodiment, the liner 26 preferably includes silicon oxide, the lower level passivation layer 32 preferably includes silicon nitride, and the upper level passivation layer 34 preferably includes plasma enhanced oxide (PEOX).

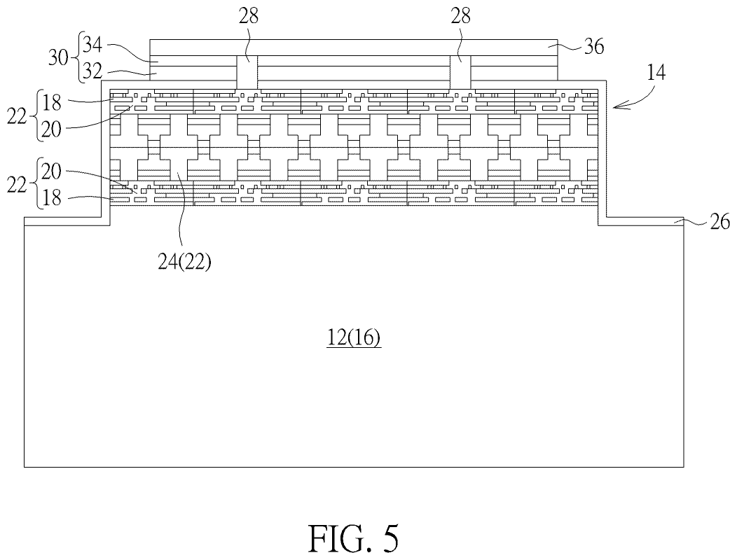

Next, as shown in FIG. 5, a pad layer (not shown) is formed on the passivation layer 30, and then a photo-etching process is conducted to remove part of the pad layer so that sidewalls of the remaining pad layer are aligned with sidewalls of the passivation layer 30 underneath to form a bonding pad 36. In this embodiment, the pad layer or the bonding pad 36 preferably includes metal such as aluminum (Al). Nevertheless, the bonding pad 36 could also include copper (Cu), silver (Ag), gold (Au), nickel (Ni), tungsten (W), or alloy thereof.

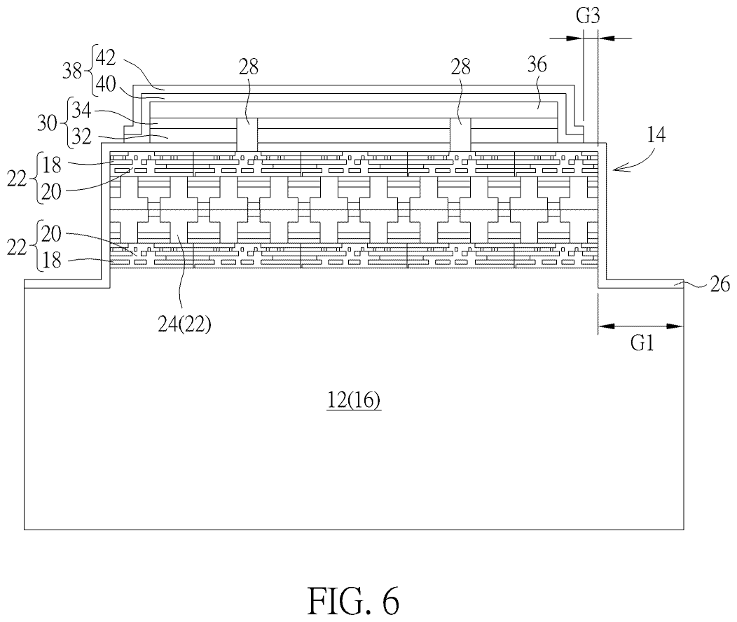

Next, as shown in FIG. 6, another passivation layer 38 is formed on the bonding pad 36. For instance, a passivation layer 40 and another passivation layer 42 could be formed on the surface of the bonding pad 36, the top wafer 14, and the bottom wafer 12, and a photo-etching process is conducted to remove part of the passivation layer 42 and part of the passivation layer 40 for forming a gap G3 between an edge of the remaining passivation layers 40, 42 and an edge of the metal interconnect structure 22. According to an embodiment of the present invention, the gap G3 is less than the aforementioned gap G2 and the gap G1, in which the gap G2 could be two times to five times of the gap G3 and the gap G1 could be two times to 20 times of the gap G3. Moreover, the lower level passivation layer 40 is preferably made of silicon oxide while the upper level passivation layer 42 is made of silicon nitride (SiN). This completes the fabrication of a semiconductor device according to an embodiment of the present invention.

Referring again to FIG. 6, FIG. 6 further illustrates a structural view of a semiconductor device according to an embodiment of the present invention. As shown in FIG. 6, the semiconductor device includes a top wafer 14 bonded to a bottom wafer 12, in which the top wafer 14 includes a metal interconnect structure 22, a liner 26 disposed and extending from the top surface of the metal interconnect structure 22 of the top wafer 14 to the sidewalls of the metal interconnect structure 22 and edge surface of the substrate 16 of the bottom wafer 12, a bonding pad 36 disposed on the metal interconnect structure 22, a passivation layer 30 disposed between the metal interconnect structure and the bonding pad 36, a plurality of deep vias 28 disposed in the passivation layer 30, and another passivation layer 38 disposed on sidewalls of the bonding pad 36.

Specifically, the passivation layer 38 is a dual layer structure having a passivation layer 40 and passivation layer 42, each of the passivation layers 40, 42 disposed on sidewalls of the bonding pad 36 includes a L-shape cross-section, a gap G3 is between an edge of the passivation layers 40, 42 and an edge of the metal interconnect structure 22, and another gap G1 is between an edge of the metal interconnect structure 22 and an edge of the substrate 16 of the bottom wafer 12. Preferably, the gap G3 is less than the gap G1 and the gap G1 could be two times to 20 times of the gap G3.

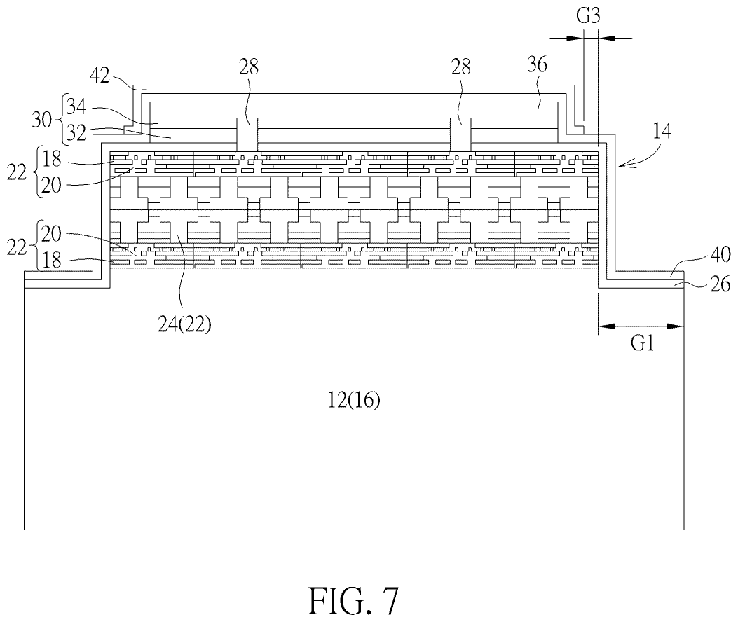

Referring to FIG. 7, FIG. 7 further illustrates a structural view of a semiconductor device according to an embodiment of the present invention. As shown in FIG. 7, in contrast to the edge of the two passivation layers 40, 42 are aligned and at the same time having a gap G3 with the edge of the metal interconnect structure 22 as shown in FIG. 6, since the liner 26 and the lower passivation layer 40 are both made of silicon oxide, it would also be desirable to only pattern the upper passivation layer 42 made of SiN during patterning of the passivation layers 40, 42 so that the lower passivation layer 40 would be covering the entire surface of the liner 26 on sidewalls of the metal interconnect structure 22 and edge portion of the substrate 16 of the bottom wafer 12 while the edges of the passivation layer 40 and the liner 26 are aligned. In this embodiment, the gap G3 is only formed between the edge of the passivation layer 42 and the edge of the metal interconnect structure 22, which is also within the scope of the present invention.

Overall, the present invention first bonds a top wafer to a bottom wafer, conducts an edge trimming process to remove part of the top wafer, forms a pad layer on the top wafer, conducts a first etching process to remove part of the pad layer to form a bonding pad 36, forms a passivation layer 38 on the bonding pad, and then conducts a second etching process to remove part of the passivation layer so that the remaining passivation layer is disposed on sidewalls of the bonding pad while forming a gap G3 between edge of the passivation layer and edge of the metal interconnect structure 22 underneath. According to a preferred embodiment of the present invention, using the aforementioned approach to conduct a wafer to wafer bonding process not only prevents wafer edge from chipping and increases die production efficiency and quality, but also reduces arcing phenomenon on bonding pad region significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
bonding a top wafer to a bottom wafer;
performing an edge trimming process to remove part of the top wafer;
forming a pad layer on the top wafer;
performing a first etching process to remove part of the pad layer to form a bonding pad;
forming a first passivation layer on the bonding pad; and
performing a second etching process to remove part of the first passivation layer.

2. The method of claim 1, wherein the top wafer comprises a metal interconnect structure, the method further comprising:
forming a second passivation layer on the metal interconnect structure;
forming a deep via in the second passivation layer;
forming the pad layer on the second passivation layer;
performing the first etching process to form the bonding pad; and
forming the first passivation layer on the bonding pad.

3. The method of claim 2, further comprising forming the second passivation layer after performing the edge trimming process.

4. The method of claim 2, further comprising performing the edge trimming process to form a first gap between an edge of the metal interconnection structure and the bottom wafer.

5. The method of claim 2, further comprising performing the second etching process to form a second gap between an edge of the first passivation layer and an edge of the metal interconnect structure.

6. The method of claim 1, further comprising forming the first passivation layer on a top surface and a sidewall of the bonding pad.

7. The method of claim 1, wherein the first passivation layer on a sidewall of the bonding pad comprises a L-shape.

8. The method of claim 1, wherein the first passivation layer comprises:
a third passivation layer; and
a fourth passivation layer on the third passivation layer.

9. The method of claim 8, wherein the third passivation layer and the fourth passivation layer comprise different materials.

10. The method of claim 1, wherein the pad layer comprises aluminum (Al).

11. A semiconductor device, comprising:
a top wafer bonded to a bottom wafer, wherein the top wafer comprises:
a metal interconnect structure;
a bonding pad on the metal interconnect structure; and
a first passivation layer on a sidewall of the bonding pad; and
a first gap between an edge of the first passivation layer and an edge of the metal interconnect structure.

12. The semiconductor device of claim 11, further comprising:
a second passivation layer between the metal interconnect structure and the bonding pad; and
a deep via in the second passivation layer.

13. The semiconductor device of claim 12, wherein the first passivation layer is on sidewalls of the bonding pad and the second passivation layer.

14. The semiconductor device of claim 11, wherein the first passivation layer on a sidewall of the bonding pad comprises a L-shape.

15. The semiconductor device of claim 11, wherein the first passivation layer comprises:
a third passivation layer; and
a fourth passivation layer on the third passivation layer.

16. The semiconductor device of claim 15, wherein the third passivation layer and the fourth passivation layer comprise different materials.

17. The semiconductor device of claim 11, further comprising a second gap between the metal interconnect structure and the bottom wafer.

18. The semiconductor device of claim 11, wherein the bonding pad comprises aluminum (Al).
